(19) United States
(12) Patent Application Publication
(10) Pub. No.: US 2025/0266411 A1
(43) Pub. Date: Aug. 21, 2025

(54) DISPLAY APPARATUS

(71) Applicant: Samsung Electronics Co., Ltd., Suwon-si (KR)

(72) Inventors: Jonghoon Ha, Suwon-si (KR); Punjae Choi, Suwon-si (KR); Juhyun Kim, Suwon-si (KR); Joonwoo Jeon, Suwon-si (KR)

(21) Appl. No.: 18/791,624

(22) Filed: Aug. 1, 2024

(30) Foreign Application Priority Data
Feb. 16, 2024 (KR) 10-2024-0022486

(51) Int. Cl. H01L 25/18; H01L 27/15

(52) U.S. Cl. CPC H01L 25/18; H10H 29/142

(57) ABSTRACT

A display apparatus includes a first semiconductor layer having a first LED cell and a second LED cell; first and second electrode pads respectively electrically connected to the first and second LED cells; a first common electrode pad electrically connected to the first semiconductor layer; a first insulating layer between the first passivation layer and a circuit board; a second semiconductor layer between the first insulating layer and the circuit board and including a third LED cell; a third electrode pad electrically connected to the third LED cell; individual electrodes electrically connecting the first to third electrode pads and a driving circuit; and a common electrode electrically connecting the first common electrode pad and the driving circuit.

### CROSS-REFERENCE TO RELATED APPLICATION(S)

This application claims benefit of priority to Korean Patent Application No. 10-2024-0022486 filed on Feb. 16, 2024, in the Korean Intellectual Property Office, the disclosure of which is incorporated herein by reference in its entirety.

### BACKGROUND

The present inventive concept relates to a display apparatus equipped with a micro LED.

Semiconductor light-emitting diodes (LEDs) may be used not only as light sources for lighting devices, but also as light sources for various electronic products. In particular, LEDs may be widely used as light sources for various display apparatuses such as TVs, mobile phones, PCs, laptop PCs, PDAs, etc.

Existing display apparatuses may include a display panel including a liquid crystal display (LCD), and a backlight, but recently, a type of display apparatus using LEDs as pixels and which does not separately require a backlight has been developed. Such a display apparatus may not only be miniaturized, but also may be implemented as a high-brightness display apparatus having superior light efficiency, as compared to LCDs.

### SUMMARY

An aspect of embodiments of the present inventive concept is to provide a high-efficiency display apparatus that may be manufactured using a simplified process.

According to an aspect of the present inventive concept, a display apparatus includes a circuit board comprising a driving circuit; and a pixel array on the circuit board, in which pixel units respectively including a plurality of sub-pixels are arranged, the pixel array including a plurality of LED cells corresponding to the plurality of sub-pixels, respectively, wherein the pixel array includes a first semiconductor layer having a first LED cell and a second LED cell, facing the circuit board; a first passivation layer on at least a portion of the first LED cell and on at least a portion of the second LED cell; first and second electrode pads passing through the first passivation layer and respectively electrically connected to the first and second LED cells; a first common electrode pad passing through the first passivation layer and electrically connected to the first semiconductor layer; a first insulating layer between the first passivation layer and the circuit board; a second semiconductor layer between the first insulating layer and the circuit board and having a third LED cell facing the circuit board; a second passivation layer on at least a portion of the third LED cell; a third electrode pad passing through the second passivation layer and electrically connected to the third LED cell; a second insulating layer between the second passivation layer and the circuit board; individual electrodes passing through one or more of the first insulating layer, the second insulating layer, or the second semiconductor layer, and electrically connecting the first to third electrode pads and the driving circuit; and a common electrode passing through the first and second insulating layers and the second semiconductor layer, and electrically connecting the first common electrode pad and the driving circuit.

According to an aspect of the present inventive concept, a display apparatus includes a circuit board including a driving circuit and bonding electrodes electrically connected to the driving circuit; and a pixel array on the circuit board and in which pixel units respectively including a plurality of sub-pixels are arranged, wherein the pixel array includes a plurality of LED cells corresponding to the plurality of sub-pixels, respectively, each of the plurality of LED cells including a first conductivity-type semiconductor layer, an active layer, and a second conductivity-type semiconductor layer, and including a first group of LED cells, and a second group of LED cells, located on different levels in a direction perpendicular to a plane defined by the circuit board; electrode pads electrically connected to the second conductivity-type semiconductor layer of each of the plurality of LED cells; a first common electrode pad electrically connected to the first conductivity-type semiconductor layer of the first group of LED cells; a second common electrode pad electrically connected to the first conductivity-type semiconductor layer of the second group of LED cells; a common electrode electrically connecting the first and second common electrode pads and one of the bonding electrodes corresponding thereto; and individual electrodes electrically connecting the electrode pads to the corresponding bonding electrodes, wherein the number of the first group of LED cells is different from the number of the second group of LED cells.

According to an aspect of the present inventive concept, a display apparatus includes a circuit board comprising a driving circuit; and a pixel array on the circuit board, and in which pixel units respectively including a plurality of sub-pixels are arranged, wherein the pixel array includes a plurality of LED cells corresponding to the plurality of sub-pixels, respectively, and respectively including a first conductivity-type semiconductor layer, an active layer, and a second conductivity-type semiconductor layer; a common electrode electrically connecting the first conductivity-type semiconductor layer of each of the plurality of LED cells and the driving circuit; and individual electrodes electrically connecting the second conductivity-type semiconductor layer of each of the plurality of LED cells and the driving circuit, wherein the plurality of LED cells includes a first LED cell, a second LED cell, and a third LED cell, configured to emit light of different wavelengths, the first LED cell and the second LED cell are located on a first level from the circuit board, and the third LED cell is located on a second level, lower than the first level, such hat the second level is closer to the circuit board than the first level.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a schematic perspective view of a display apparatus according to an example embodiment.

FIGS. 2A and 2B are schematic plan views of display apparatuses, respectively, according to example embodiments.

FIG. 3 is a schematic cross-sectional view of a display apparatus according to an example embodiment.

FIG. 4 is a schematic cross-sectional view of a display apparatus according to an example embodiment.

FIG. 5 is a schematic cross-sectional view of a display apparatus according to an example embodiment.

FIG. 6 is a schematic cross-sectional view of a display apparatus according to an example embodiment.

FIG. 7 illustrates a driving circuit implemented in a display apparatus according to an example embodiment.

FIGS. 8A to 8P are cross-sectional views of main processes illustrating a method of manufacturing a display apparatus according to an example embodiment.

FIG. 9 is a conceptual diagram of an electronic device to which a display apparatus according to an example embodiment is applied.

### DETAILED DESCRIPTION

Hereinafter, example embodiments will be described with reference to the accompanying drawings. Hereinafter, it can be understood that terms such as ‘on,’ ‘upper,’ ‘upper portion,’ ‘upper surface,’ ‘below,’ ‘lower,’ ‘lower portion,’ ‘lower surface,’ ‘side surface,’ and the like may be denoted by reference numerals and refer to the drawings, except where otherwise indicated.

Additionally, ordinal numbers such as “first,” “second,” “third,” or the like may be used as labels for specific elements, steps, operations, directions, or the like to distinguish various elements, steps, operations, directions, or the like from each other. Terms that may not be described using “first,” “second,” or the like in the specification may still be referred to as “first” or “second” in the claims. Additionally, terms referenced by a particular ordinal number (e.g., “first” in a particular claim) may be described elsewhere with a different ordinal number (e.g., “second” in the specification or another claim). As used herein, the term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination

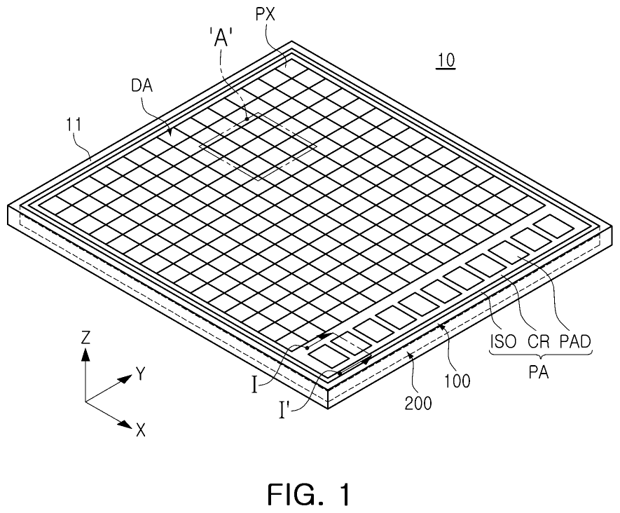

FIG. 1 is a schematic perspective view of a display apparatus 10 according to an example embodiment.

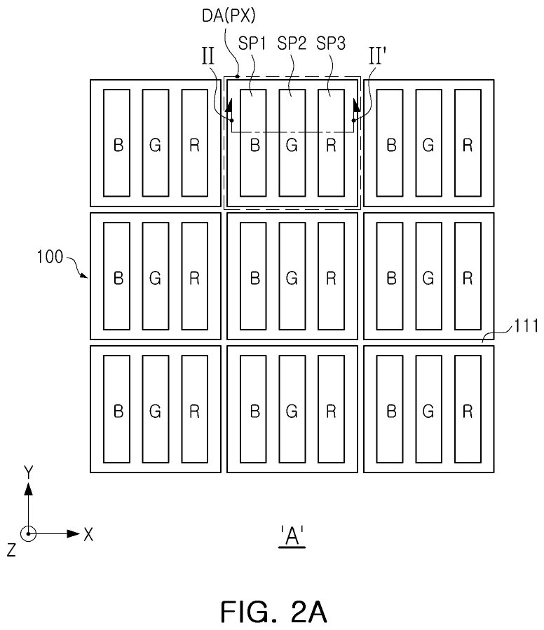

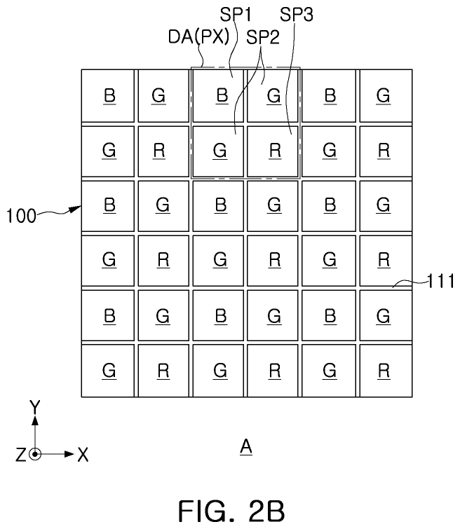

FIGS. 2A and 2B are schematic plan views of display apparatuses 10, respectively, according to an example embodiment.

Referring to FIGS. 1, 2A, and 2B, a display apparatus 10 according to the present embodiment may include a circuit board 200 including driving circuits, and a pixel array 100 disposed on the circuit board 200 and in which a plurality of pixels PX are arranged. The display apparatus 10 may further include a frame 11 at least partially surrounding the circuit board 200 and the pixel array 100.

The circuit board 200 may include a driving circuit including thin film transistor (TFT) cells. In some embodiments, the circuit board 200 may additionally include a different driving circuit, in addition to the driving circuit for the display apparatus. In some embodiments, the circuit board 200 may include a flexible board, and the display apparatus 10 may be implemented as a display apparatus having a curved profile.

The pixel array 100 may include a display region DA and a peripheral region PA on at least one side of the display region DA. The display region DA may include an LED module for display. The pixel array 100 may include a display region DA in which a plurality of pixels PX are arranged. The peripheral region PA may include pad regions PAD, a connection region CR electrically connecting the plurality of pixels PX and the pad regions PAD, and an edge region ISO. In FIG. 1, the plurality of pixels PX are illustrated as being arranged in a 15×15 pattern, but columns and rows may be implemented as any appropriate number, for example, 1,024×768 or the like. For example, depending on a desired resolution, the plurality of pixels PX may have different arrangements.

Each of the plurality of pixels PX may include first to third sub-pixels SP1, SP2, and SP3 configured to emit light of a specific wavelength, for example, a specific color, to provide a color image. For example, the first to third sub-pixels SP1, SP2, and SP3 may be configured to emit blue (B) light, green (G) light, and red (R) light, respectively. In some embodiments, in each of the pixels PX (or pixel unit), the first to third sub-pixels SP1, SP2, and SP3 may have a pattern arranged side by side in one direction (e.g., X-direction) (see FIG. 2A). However, embodiments the present inventive concept is not limited thereto, and in some embodiments, the first to third sub-pixels SP1, SP2, and SP3 may be arranged in a different pattern, such as a Bayer pattern (see FIG. 2B).

Specifically, as illustrated in FIG. 2B, each of the pixels PX may include first and third sub-pixels SP1 and SP3 (e.g., B and R) arranged in a first diagonal direction, and two second sub-pixels SP2 (e.g., G) arranged in a second diagonal direction, intersecting the first diagonal direction. In the present embodiment, each of the pixels PX are illustrated as having first to third sub-pixels SP1, SP2, and SP3 arranged in a 2×2 Bayer pattern, but embodiments of the present inventive concept are not limited thereto, and in other embodiments, each of the pixels PX may be configured in a different arrangement such as 3×3, 4×4, or the like. Additionally, in some embodiments, each of the pixels PX may include a sub-pixel configured to emit light in a color, different from the illustrated colors R, G, and B, for example, yellow light.

The pad regions PAD may be disposed on at least one side of the plurality of pixels PX along an edge of the display apparatus 10. The pad regions PAD may be electrically connected to the plurality of pixels PX and the driving circuits of the circuit board 200. The pad regions PAD may electrically connect an external device and the display apparatus 10. In some embodiments, the number of pad regions PAD may be changed and may be determined, for example, depending on the number of pixels PX, a driving method of a TFT circuit in the circuit board 200, or the like.

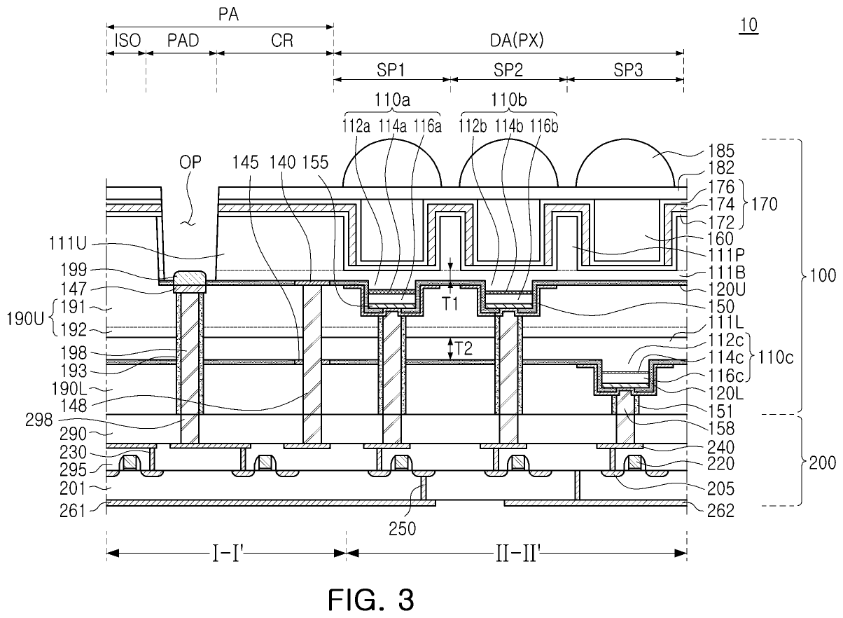

The connection region CR may be a region located between the plurality of pixels PX and the pad regions PAD. A wiring structure, such as a common electrode or the like, that may be electrically connected to the plurality of pixels PX, may be disposed in the connection region CR. The edge region ISO may be a region along edges of the pixel array 100. The edge region ISO may be a region in which an upper semiconductor layer 111U is not disposed (see FIG. 3).

The frame 11 may be arranged around the pixel array 100, and may serve as a guide for defining an arrangement space of the pixel array 100. The frame 11 may include one or more materials, such as a polymer, a ceramic, a semiconductor, and/or metal, for example. For example, the frame 11 may include a black matrix. The frame 11 is not limited to the black matrix, and may include a white matrix or a structure having a different color, depending on the purpose of the display apparatus 10. For example, the white matrix may include a reflective material or a scattering material. In FIG. 1, the display apparatus 10 is illustrated as having a rectangular planar structure, but may have a different shape, depending on embodiments.

FIG. 3 is a schematic cross-sectional view of a display apparatus 10 according to an example embodiment. FIG. 3 can be understood as a combination of a cross-section taken along line I-I′ of FIG. 1 (peripheral region PA) and a cross-section taken along line II-II′ of FIG. 2 (display region DA).

Referring to FIG. 3, a display apparatus 10 of an example embodiment may include a circuit board 200 and a pixel array 100 disposed on the circuit board 200.

The circuit board 200 may include a semiconductor substrate 201, a driving circuit including driving elements 220 including TFT cells formed on the semiconductor substrate 201, interconnections 230 electrically connected to the driving elements 220, wiring lines 240 on the interconnections 230, and a circuit insulating layer 295 on and at least partially covering the driving circuit. In the present embodiment, the circuit board 200 may further include a bonding insulating layer 290 on the circuit insulating layer 295, and bonding electrodes 298 disposed in the bonding insulating layer 290 and connected to the wiring lines 240.

The semiconductor substrate 201 may include impurity regions including source/drain regions 205. The semiconductor substrate 201 may include, for example, a semiconductor, such as silicon (Si) or germanium (Ge), or a compound semiconductor such as SiGe, SiC, GaAs, InAs, or InP. The semiconductor substrate 201 may further include through-electrodes 250, such as a through-silicon-via (TSV) electrically connected to the driving circuit, and first and second substrate wiring lines 261 and 262 electrically connected to the through-electrodes 250.

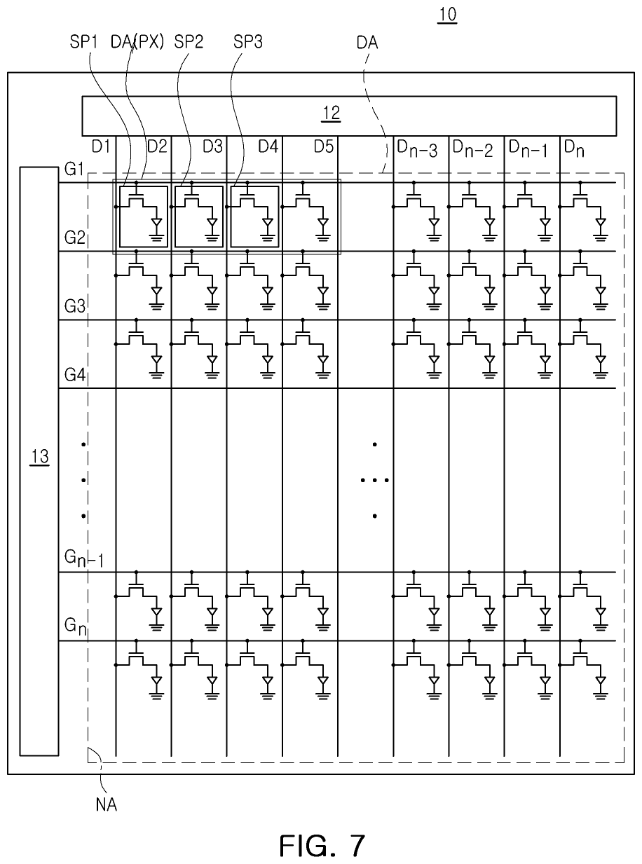

The driving circuit may include a circuit for controlling driving of a pixel, particularly a sub-pixel. A source region 205 of the TFT cells may be electrically connected to one electrode of LED cells 110a, 110b, and 110c through the interconnection 230, the wiring lines 240, and the bonding electrodes 298. For example, a drain region 205 of the TFT cells may be electrically connected to the first wiring line 261 through the through-electrode 250, and the first wiring line 261 may be electrically connected to a data line. Gate electrodes of the TFT cells may be electrically connected to the second wiring line 262 through the through-electrode 250, and the second wiring line 262 may be electrically connected to the gate line. This circuit configuration and operation will be described in more detail with reference to FIG. 7 below.

Upper surfaces of the bonding electrodes 298 and upper surfaces of the bonding insulating layer 290 may form an upper surface of the circuit board 200. The bonding electrodes 298 may be bonded to electrodes 148, 158, and 198 of the pixel array 100 to provide an electrical connection path. The bonding electrodes 298 may include a conductive material, for example, copper (Cu). The bonding insulating layer 290 may be bonded to a lower insulating layer 190L of the pixel array 100. For example, the bonding insulating layer 290 may include one or more materials, such as silicon oxide (SiO), silicon nitride (SIN), silicon carbonitride (SiCN), silicon oxycarbide (SiOC), silicon oxynitride (SiON), and/or silicon oxycarbonitride (SiOCN).

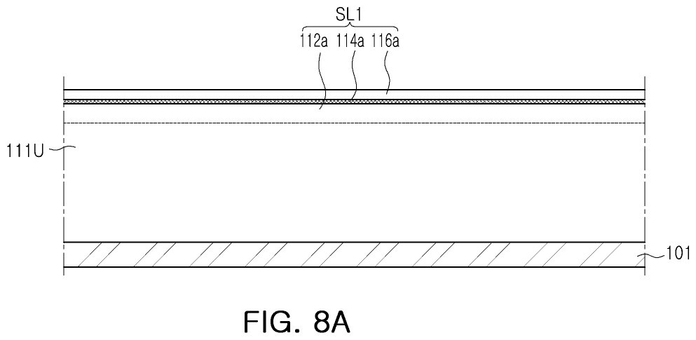

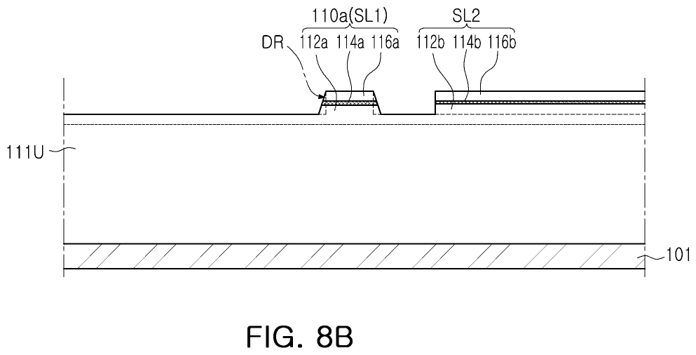

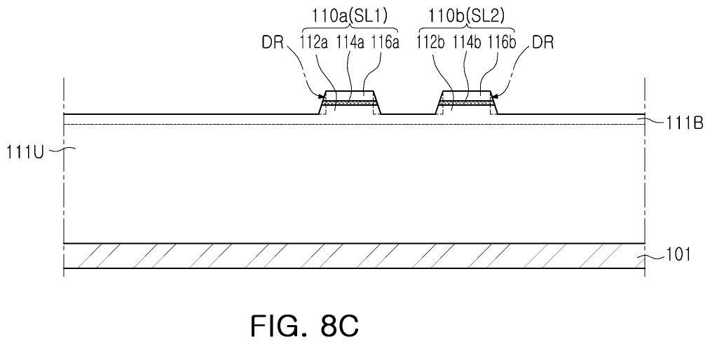

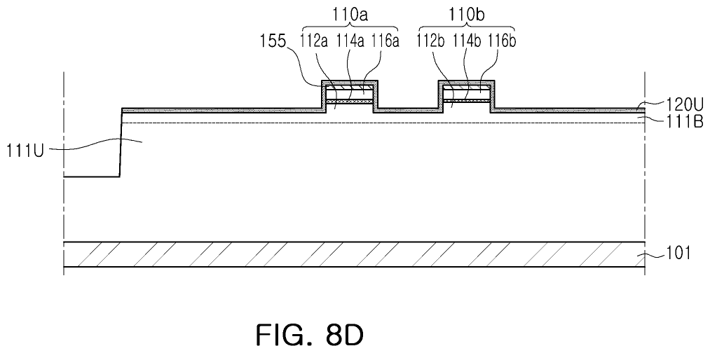

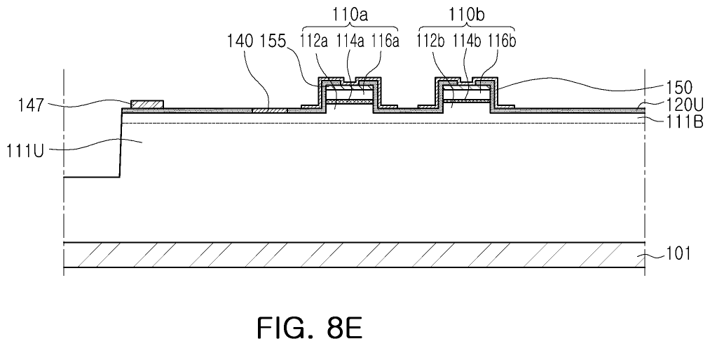

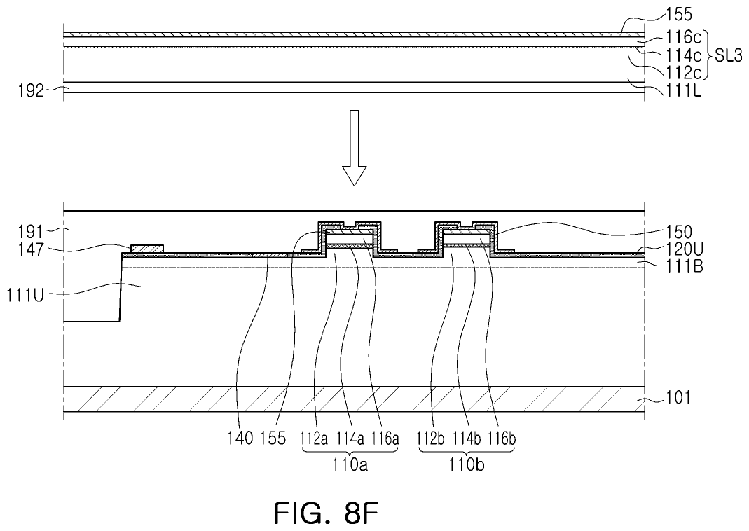

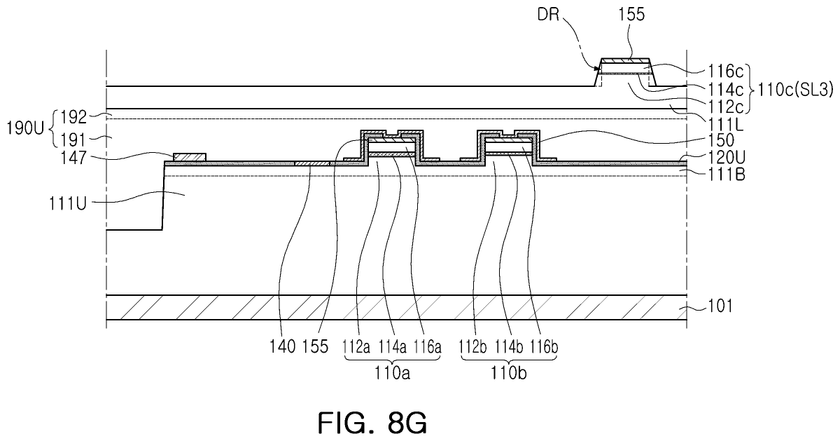

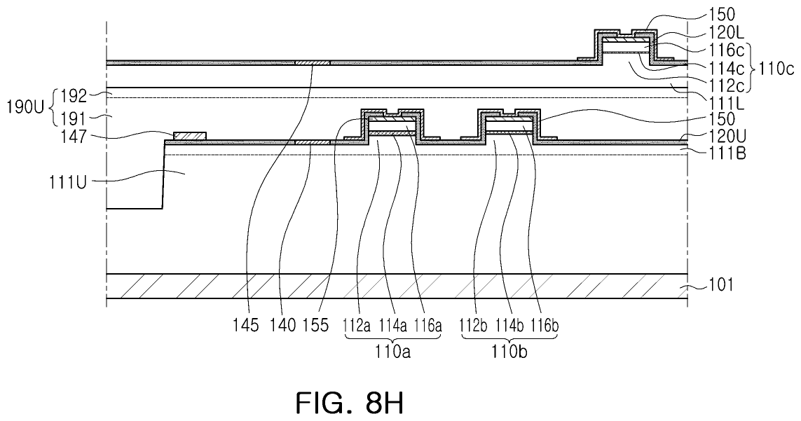

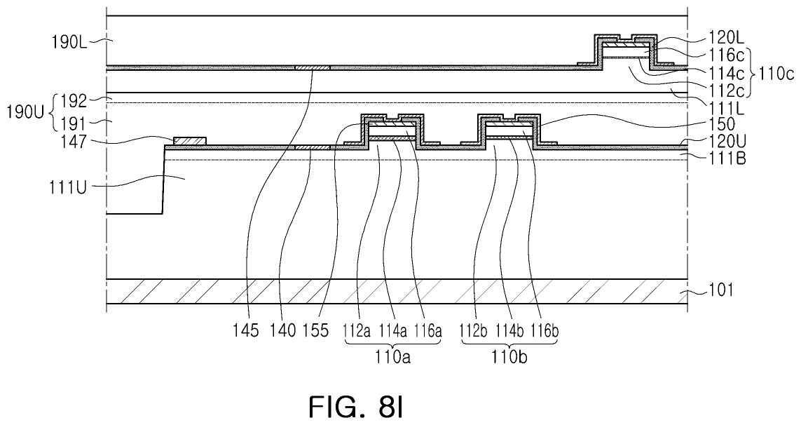

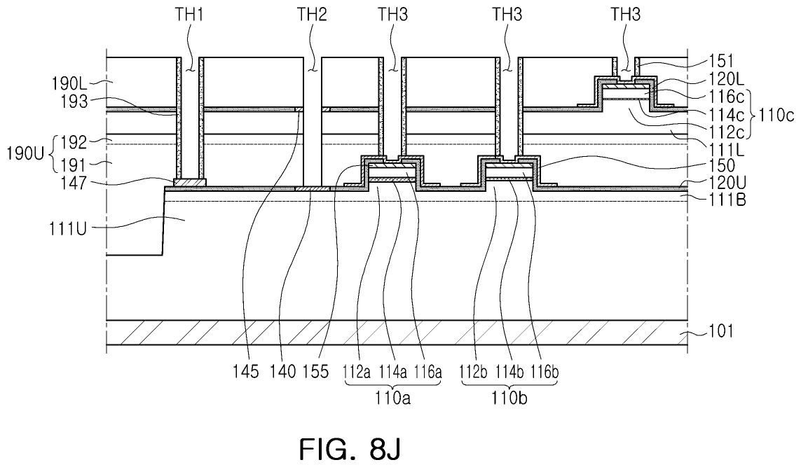

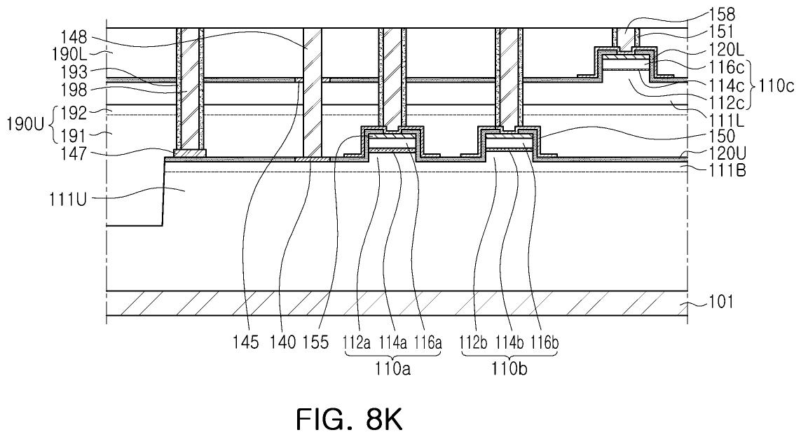

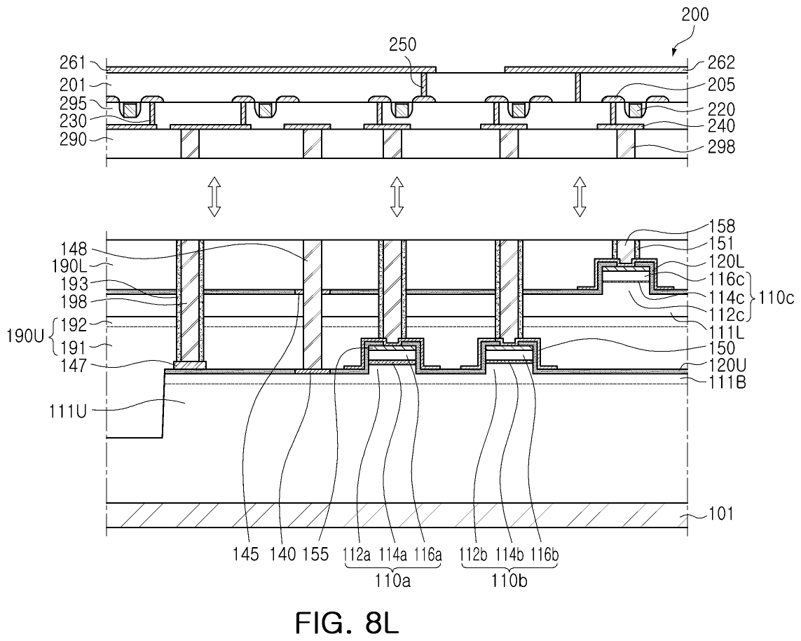

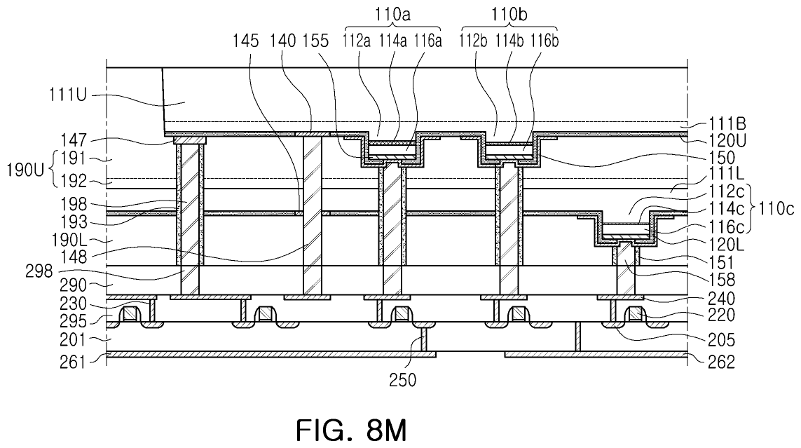

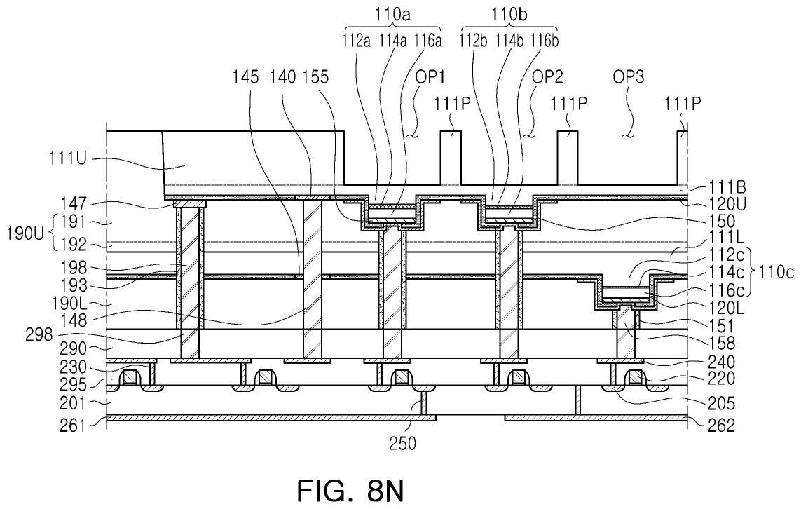

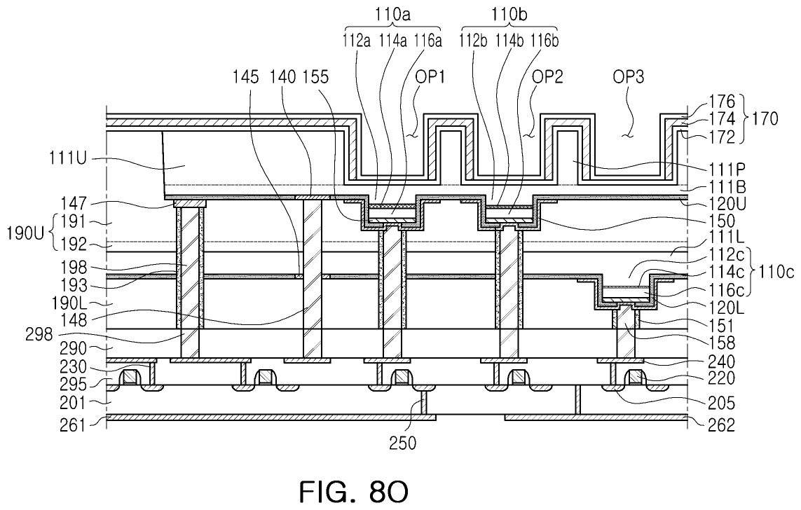

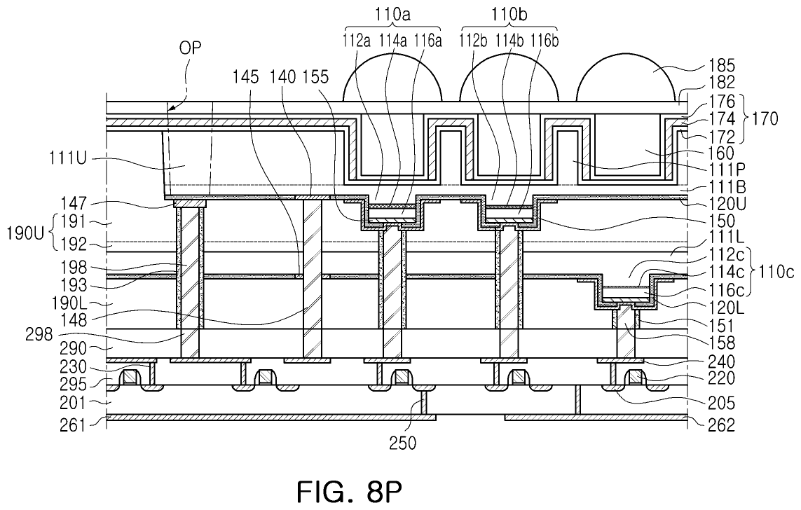

The pixel array 100 may include a plurality of LED cells 110a, 110b, and 110c for first to third sub-pixels SP1, SP2, and SP3. The plurality of LED cells 110a, 110b, and 110c may be arranged in a plurality of columns and a plurality of rows in plan view (see FIGS. 2A and 2B). An angle between lower and side surfaces of each of the LED cells 110a, 110b, and 110c may be a right angle or an angle similar to the right angle. For example, the angle may range from about 85 degrees to about 95 degrees according to different embodiments. The LED cells 110a, 110b, and 110c may be obtained by sequentially performing a dry etching process and a wet etching process (see FIGS. 8B, 8C, and 8G).

Each of the plurality of LED cells 110a, 110b, and 110c may include a first conductivity-type semiconductor layer (112a, 112b, and 112c), an active layer (114a, 114b, and 114c), and a second conductivity-type semiconductor layer (116a, 116b, and 116c). Each of the plurality of LED cells 110a, 110b, and 110c may be defined by a side surface of the active layer (114a, 114b, and 114c) and a side surface of the second conductivity-type semiconductor layer (116a, 116b, and 116c).

The first conductivity-type semiconductor layer (112a, 112b, and 112c), the active layer (114a, 114b, and 114c), and the second conductivity-type semiconductor layer (116a, 116b, and 116c) may be nitride epitaxial layers. A first conductivity-type semiconductor layer 112 and a second conductivity-type semiconductor layer 116 may be a nitride semiconductor layer having compositions of n-type and p-type InₓAl_{y}Ga_{1-x-y}N (0≤x<1, 0≤y<1, 0≤x+y<1), respectively. For example, the first conductivity-type semiconductor layer (112a, 112b, and 112c) may be an n-type gallium nitride (n-GaN) layer doped with silicon (Si), germanium (Ge), or carbon (C), and the second conductivity-type semiconductor layer (116a, 116b, and 116c) may be a p-type gallium nitride (p-GaN) layer doped with magnesium (Mg) or zinc (Zn).

Depending on embodiments, the first conductivity-type semiconductor layer (112a, 112b, and 112c) and the second conductivity-type semiconductor layer (116a, 116b, and 116c) may be provided as an aluminum-indium-gallium-phosphide (AlInGaP)-based semiconductor layer or an aluminum-indium-gallium-arsenide (AlInGaAs)-based semiconductor layer, in addition to the nitride semiconductor. Each of the first conductivity-type semiconductor layer (112a, 112b, and 112c) and the second conductivity-type semiconductor layer (116a, 116b, and 116c) may be provided as a single layer, but may also include a plurality of layers with different characteristics such as a doping concentration, a composition, or the like.

Contact layers 155 may be disposed below the plurality of LED cells 110a, 110b, and 110c, and may be connected to the second conductivity-type semiconductor layer (116a, 116b, and 116c). The contact layers 155 may be formed to be on and cover almost entirely a lower surface of the second conductivity-type semiconductor layer (116a, 116b, and 116c).

Electrode pads 150 may pass through an upper passivation layer 120U and a lower passivation layer 120L, and may be electrically connected to the contact layers 155. The electrode pads 150 may extend to be on and at least partially cover each of the side surfaces of the plurality of LED cells 110a, 110b, and 110c. The electrode pads 150 may include a reflective metal material. For example, the electrode pads 150 may include one or more materials, such as, silver (Ag), nickel (Ni), aluminum (Al), chromium (Cr), rhodium (Rh), iridium (Ir), palladium (Pd), ruthenium (Ru), magnesium (Mg), zinc (Zn), platinum (Pt), gold (Au), copper (Cu), titanium (Ti), tantalum (Ta), and/or tungsten (W). In some embodiments, the electrode pads 150 may include a compound thereof such as TaN and/or TiN, or a transparent electrode material such as ITO, IZO, or GAZO. In some embodiments, the electrode pads 150 may include a single-layer or multi-layer structure of a conductive material.

The active layer (114a, 114b, and 114c) may emit light with a predetermined energy by recombination of an electron and a hole. The active layer (114a, 114b, and 114c) may have a single quantum well (SQW) structure or a multiple quantum well (MQW) structure in which a quantum barrier layer and a quantum well layer are alternately arranged. For example, the quantum well layer and the quantum barrier layer may be InₓAl_{y}Ga_{1-x-y}N (0≤x≤1, 0≤y≤1, 0≤x+y≤1) layers having different compositions. For example, the quantum well layer may be an InₓGa₁₋ₓN (0<x≤1) layer, and the quantum barrier layer may be a GaN layer or an AlGaN layer.

Each of the plurality of LED cells 110a, 110b, and 110c may be a micro LED, and may be configured to emit light having different wavelengths. For example, the pixel array 100 may include first to third LED cells 110a, 110b, and 110c, directly emitting blue (B) light, green (G) light, and red (R) light. In example embodiments, a first active layer 114a of the first LED cell 110a may be configured to emit blue light, for example, light having a wavelength of about 440 nm to about 480 nm. A second active layer 114b of the second LED cell 110b may be configured to emit green light, for example, light having a wavelength of about 510 nm to about 550 nm. Additionally, a third active layer 114c of the third LED cell 110c may be configured to emit red light, for example, light having a wavelength of about 610 nm to about 650 nm.

In an example embodiment, the pixel array 100 may include a first group of LED cells 110a and 110b located on the same level as each other, and a second group of LED cells 110c located on a different level from the first group of LED cells 110a and 110b. The level may be a vertical level, which corresponds to a direction perpendicular to a plane defined by the circuit board 200 as shown in the cross-sectional view of FIG. 3. For example, the first group of LED cells 110a and 110b may be located on a first level from the circuit board 200, and the second group of LED cells 110c may be located on a second level, lower than the first level in the vertical direction where the plane defined by the circuit board 200 provides a base reference level. The number of the first group of LED cells 110a and 110b may be different from the number of the second group of LED cells 110c. For example, the number of the second group of LED cells 110c may be less than the number of the first group of LED cells 110a and 110b.

In an example embodiment, the first group of LED cells 110a and 110b may include first and second LED cells 110a and 110b configured to emit blue (B) light and green (G) light, and the second group of LED cells 110c may include a third LED cell 110c configured to emit red (R) light. A gap between the third LED cell 110c and the circuit board 200 may be smaller than a gap between the first and second LED cells 110a and 110b and the circuit board 200. The third LED cell 110c may not overlap the first and second LED cells 110a and 110b in horizontal and vertical directions where the horizontal vertical direction is a direction parallel to a plane defined by the circuit board 200 and the vertical direction is perpendicular to the plane defined by the circuit board 200. The first LED cell 110a, the second LED cell 110b, and the third LED cell 110c may not overlap each other in the vertical direction. Therefore, optical paths for the first LED cell 110a, the second LED cell 110b, and the third LED cell 110c toward a microlens 185 may be secured, and light loss may be reduced or minimized.

According to example embodiments, an upper semiconductor layer 111U and a lower semiconductor layer 111L, in which the first group of LED cells 110a and 110b and the second group of LED cells 110c are respectively formed, may be integrally or monolithically bonded to simplify a manufacturing process of the display apparatus 10 and to improve a yield thereof. Additionally, because the first group of LED cells 110a and 110b and the second group of LED cells 110c share a common electrode 148, a size of the pixel array 100 may be reduced.

A pixel array 100 of an example embodiment may include the upper semiconductor layer 111U (or ‘first semiconductor layer’) on which the first group of LED cells 110a and 110b (e.g., the first and second LED cells 110a and 110b) are formed, and the lower semiconductor layer 111L (or ‘second semiconductor layer’) on which the second group of LED cells 110c (e.g., the third LED cell 110c) are formed.

The upper semiconductor layer 111U can be understood as an epitaxial layer continuously grown on one growth substrate. The upper semiconductor layer 111U may include a first conductivity-type semiconductor base layer 111B shared by the first group of LED cells 110a and 110b. In FIG. 3, a dotted line crossing the upper semiconductor layer 111U can be understood as a virtual boundary distinguishing the first conductivity-type semiconductor base layer 111B.

Some regions of the upper semiconductor layer 111U (e.g., first conductivity-type semiconductor layers 112a and 112b, active layers 114a and 114b, and second conductivity-type semiconductor layers 116a and 116b) may be separated as the first group of LED cells 110a and 110b, but other regions of the upper semiconductor layer 111U (e.g., the first conductivity-type semiconductor base layer 111B) may not be separated and may be connected between the first group of LED cells 110a and 110b. The thickness T1 of the first conductivity-type semiconductor base layer 111B may be about 300 nm or more, for example, in the range of about 300 m to about 1 μm, but embodiments of the present inventive concept are not limited thereto.

The upper semiconductor layer 111U may be disposed to extend from a display region DA to a connection region CR and pad regions PAD, e.g., a region of a peripheral region PA. The upper semiconductor layer 111U may include a nitride epitaxial layer of the same type as the nitride semiconductor epitaxial layers constituting the first group of LED cells 110a and 110b. In some embodiments, the upper semiconductor layer 111U may include an undoped nitride layer, or a stack of an undoped nitride layer and a first conductivity-type (n-type) nitride layer.

The upper passivation layer 120U (or ‘first passivation layer’) may be on and cover a portion of lower surfaces and side surfaces of the first group of LED cells 110a and 110b, and may extend to the peripheral region PA. The upper passivation layer 120U may be disposed to be on and at least partially cover a lower surface of the upper semiconductor layer 111U in the connection region CR and the pad regions PAD, e.g., in the peripheral region PA. The upper passivation layer 120U may include an insulating material, for example, one or more materials, such as, SiO₂, SIN, SiCN, SiOC, SION, SiOCN, SiOCN, HfOₓ, AlOₓ, ZrOₓ, and/or AlN.

An upper common electrode pad 140 (or ‘first common electrode pad’) may pass through the upper passivation layer 120U extending into the peripheral region PA, and may be connected to the upper semiconductor layer 111U or the first conductivity-type semiconductor base layer 111B. The upper common electrode pad 140 may be disposed in the connection region CR. The upper common electrode pad 140 may be disposed in a square ring shape or a ring shape to entirely surround the pixels PX in plan view, but embodiments of the present inventive concept are not limited thereto. The upper common electrode pad 140 may include a conductive material, such as silver (Ag), nickel (Ni), aluminum (Al), chromium (Cr), rhodium (Rh), iridium (Ir), palladium (Pd), ruthenium (Ru), magnesium (Mg), zinc (Zn), platinum (Pt), and/or gold (Au).

The upper semiconductor layer 111U may include partition structures 111P defining a plurality of sub-pixel spaces corresponding to each of the plurality of LED cells 110a, 110b, and 110c. A partition structure 111P may be a structure obtained by etching the upper semiconductor layer 111U (see FIG. 8N). In some embodiments, the partition structure 111P may be a separate structure formed of a different material (e.g., a light blocking material or a reflective material). To reduce or prevent light interference between the sub-pixels SP1, SP2, and SP3, a partition reflective layer 170 may be introduced on a surface of the partition structure 111P.

The partition reflective layer 170 may be formed on an upper surface and side walls of the partition structure 111P. The partition reflective layer 170 may include a first partition insulating film 172, a reflective metal film 174, and a second partition insulating film 176, sequentially stacked. The first partition insulating layer 172 and the second partition insulating layer 176 may include an insulating material, for example, SiO, SiN, SiCN, SiOC, SiON, and/or SiOCN. The reflective metal film 174 may include a reflective metal, for example, silver (Ag), nickel (Ni), and/or aluminum (Al). The reflective metal film 174 may be formed on an inner sidewall of a plurality of sub-pixel spaces, but may not be formed on a bottom surface thereof. Through this arrangement, light emitted from each of the LED cells 110a, 110b, and 110c may pass through a bottom surface of the plurality of sub-pixel spaces. A transparent resin portion 160 may be formed in each of the sub-pixel spaces at least partially surrounded by the partition reflective layer 170.

The transparent resin portion 160 may not include a wavelength conversion material, such as a phosphor and/or a quantum dot, and may emit light having required wavelengths (e.g., R, G, and B) in each of the sub-pixels SP1, SP2, and SP3, directly from the first to third LED cells 110a, 110b, and 110c. In some embodiments, the transparent resin portion 160 may further include a light scattering material. A planarization layer 182 and a microlens 185 may be disposed on the transparent resin portion 160.

The planarization layer 182 may be a transparent layer formed on the partition structure 111P and the upper semiconductor layer 111U, with which the transparent resin portion 160 is at least partially filled. Microlenses 185 may be disposed on the transparent resin portion 160. The microlenses 185 may be arranged to correspond to the first to third sub-pixels SP1, SP2, and SP3 on the planarization layer 182, and may concentrate light from the first to third LED cells 110a, 110b, and 110c. For example, the microlenses 185 may have a diameter greater than a width of each of the LED cells 110a, 110b, and 110c in the X- and Y-directions. The microlenses 185 may be formed as, for example, a transparent photoresist material or a transparent thermosetting resin film.

The lower semiconductor layer 111L can be understood as an epitaxial layer continuously grown on one growth substrate. The lower semiconductor layer 111L may include a first conductivity-type semiconductor layer 112c, an active layer 114c, and a second conductivity-type semiconductor layer 112c, defining the second group of LED cells 110c. The lower semiconductor layer 111L may include an epitaxial layer of the same type as the semiconductor epitaxial layers constituting the second group of LED cells 110c. The lower semiconductor layer 111L may be formed as an aluminum-indium-gallium-nitride (AlInGaN) semiconductor layer, an aluminum-indium-gallium-phosphide (AlInGaP) semiconductor layer, or an aluminum-indium-gallium-arsenide (AlInGaAs) semiconductor layer. Depending on an embodiment, the lower semiconductor layer 111L may include a semiconductor layer of a different series from the upper semiconductor layer 111U. For example, the upper semiconductor layer 111U may include a nitride semiconductor, and the lower semiconductor layer 111L may include a phosphide semiconductor or an arsenide semiconductor.

A thickness T2 of the lower semiconductor layer 111L may be about 300 nm or more, for example, in a range of about 300 m to about 1 μm. In the drawings, the thickness T2 of the lower semiconductor layer 111L is illustrated to be greater than a thickness T1 of the first conductivity-type semiconductor base layer 111B, but embodiments of the present inventive concept are not limited thereto. Depending on an embodiment, the thickness T2 of the lower semiconductor layer 111L may be the same as or smaller than the thickness T1 of the first conductivity-type semiconductor base layer 111B. The lower semiconductor layer 111L may be disposed to extend from the display region DA to almost the entirety of the connection region CR, the pad regions PAD, and the edge region ISO, e.g., the peripheral region PA.

The lower passivation layer 120L (or ‘second passivation layer’) may be on and cover a portion of lower surfaces and side surfaces of the second group of LED cells 110c, and may extend to the peripheral region PA. The lower passivation layer 120L may be disposed to be on and at least partially cover a lower surface of the lower semiconductor layer 111L in the peripheral region PA. The lower passivation layer 120L may include an insulating material, for example, one or more materials, such as, SiO₂, SiN, SiCN, SiOC, SiON, SiOCN, SiOCN, HfOₓ, AlOₓ, ZrOₓ, and/or AlN.

A lower common electrode pad 145 (or ‘second common electrode pad’) may pass through the lower passivation layer 120L extending into the peripheral region PA, and may be connected to the lower semiconductor layer 111L or the second group of LED cells 110c defined by the first conductivity-type semiconductor layer 112c. The lower common electrode pad 145 may be disposed to vertically, i.e., a direction perpendicular to a plan defined by the circuit board 200, overlap the upper common electrode pad 140. The lower common electrode pad 145 may include a conductive material, such as silver (Ag), nickel (Ni), aluminum (Al), chromium (Cr), rhodium (Rh), iridium (Ir), palladium (Pd), ruthenium (Ru), magnesium (Mg), zinc (Zn), platinum (Pt), and/or gold (Au).

An upper insulating layer 190U may be disposed between the lower semiconductor layer 111L and the upper semiconductor layer 111U. The upper insulating layer 190U may include one or more materials, such as SiO, SIN, SiCN, SiOC, SiON, and/or SiOCN. In some embodiments, the upper insulating layer 190U may include silicon oxide, or a silicon oxide-based insulating material, and may be, for example, tetraethyl-ortho-silicate (TEOS), undoped silicate glass (USG), phosphosilicate glass (PSG), borosilicate glass (BSG), borophosphosilicate glass (BPSG), fluoride silicate glass (FSG), spin-on-glass (SOG), Tonen silazene (TOSZ), or a combination thereof. The upper insulating layer 190U may include a first insulating material layer 191 and a second insulating material layer 192, bonded to each other. In FIG. 3, a dotted line crossing the upper insulating layer 190U can be understood as a virtual boundary distinguishing the first insulating material layer 191 and the second insulating material layer 192.

A lower insulating layer 190L may be disposed below the lower semiconductor layer 111L as shown in FIG. 3. The lower insulating layer 190L may include an insulating material similar to the upper insulating layer 190U. The lower insulating layer 190L may form dielectric-dielectric bonding with the bonding insulating layer 290 of the circuit board 200.

In addition, the pixel array 100 may further include individual electrodes 158 and common electrodes 148, electrically connecting the plurality of LED cells 110a, 110b, and 110c to the driving circuit of the circuit board 200. The individual electrodes 158 and the common electrodes 148 may form metal-metal bonding with the bonding electrodes 298.

The individual electrodes 158 may pass through the lower insulating layer 190L, the lower semiconductor layer 111L, and/or the upper insulating layer 190U, and may electrically connect the electrode pads 150 of each of the plurality of LED cells 110a, 110b, and 110c and the bonding electrodes 298 of the circuit board 200. A side insulating film 151 may be disposed between the individual electrodes 158 and the lower semiconductor layer 111L. The side insulating film 151 may include an insulating material, for example, SiO, SiN, SiCN, SiOC, SiON, and/or SiOCN.

The common electrodes 148 may pass through the lower insulating layer 190L, the lower semiconductor layer 111L, and/or the upper insulating layer 190U, and may electrically connect the upper common electrode pad 140 and the lower common electrode pad 145 to the bonding electrodes 298 of the circuit board 200. At least a portion of each of the common electrodes 148 may be in contact with the lower semiconductor layer 111L.

Additionally, the pixel array 100 may further include an upper connection pad 199, a lower connection pad 147, a connection electrode 198, and a side insulating film 193, disposed in the pad regions PAD. At least an upper surface of the upper connection pad 199 may be exposed through an opening OP passing through the upper semiconductor layer 111U. The upper connection pad 199 may be connected to an external device, such as an external circuit (IC) or the like, that may apply an electrical signal to the circuit board 200, by wire bonding or anisotropic conductive film (AFC) bonding. The upper connection pad 199 may electrically connect the driving circuits of the circuit board 200 and the external device. The upper connection pad 199 may include metal, such as gold (Au), silver (Ag), nickel (Ni), or the like.

The lower connection pad 147 may be disposed below the upper connection pad 199, and may connect the upper connection pad 199 and the connection electrode 198 as shown in FIG. 3. The lower connection pad 147 may include, for example, one or more materials, such as silver (Ag), nickel (Ni), aluminum (Al), chromium (Cr), rhodium (Rh), iridium (Ir), palladium (Pd), ruthenium (Ru), magnesium (Mg), zinc (Zn), platinum (Pt), and/or gold (Au). The connection electrode 198 may form metal-metal bonding with the bonding electrodes 298. The connection electrode 198 may be electrically insulated from the lower semiconductor layer 111L by the side insulating film 193.

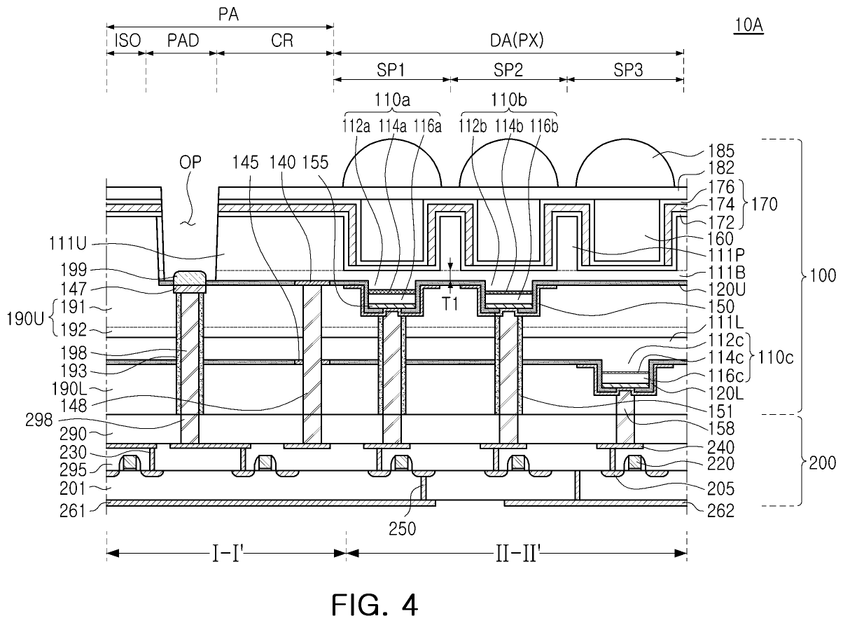

FIG. 4 is a schematic cross-sectional view of a display apparatus 10A according to an example embodiment.

Referring to FIG. 4, a display apparatus 10A of an example embodiment may have the same or similar features as those described with reference to FIGS. 1 to 3, except that at least a portion of a side insulating film 151 is omitted. The side insulating film 151 in the example embodiment may be disposed only on individual electrodes 158 passing through a lower semiconductor layer 111L. For example, the side insulating film 151 may be formed to at least partially surround the individual electrodes 158 respectively connected to a first group of LED cells 110a and 110b. A side insulating film may not be formed between the individual electrodes 158 connected to a second group of LED cells 110c and a lower insulating layer 190L.

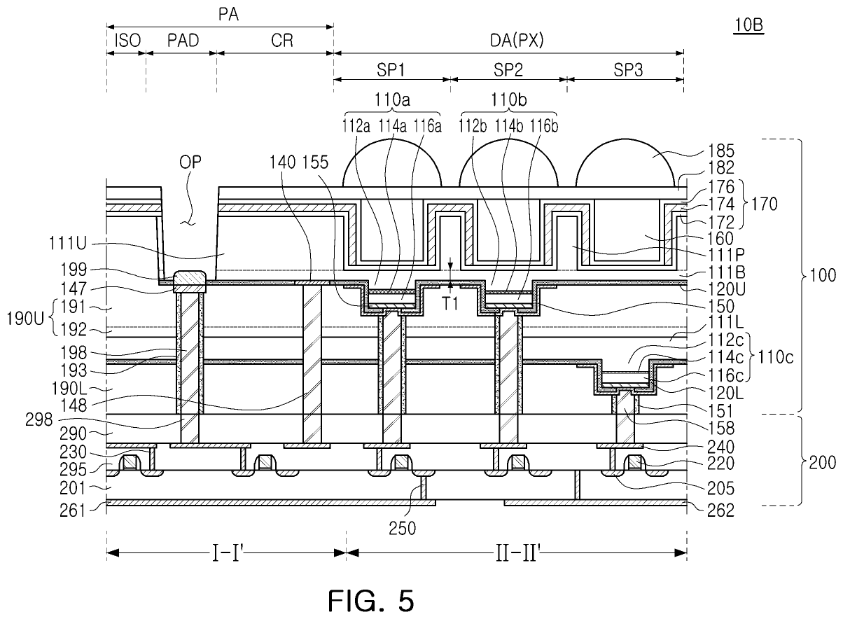

FIG. 5 is a schematic cross-sectional view of a display apparatus 10B according to an example embodiment.

Referring to FIG. 5, a display apparatus 10B of an example embodiment may have the same or similar features as those described with reference to FIGS. 1 to 4, except that a lower common electrode pad (‘145’ in FIG. 3) is omitted. Common electrodes 148 of the example embodiment may pass through a lower insulating layer 190L, a lower semiconductor layer 111L, and an upper insulating layer 190U, and may be electrically connected to an upper common electrode pad 140. In addition, the common electrodes 148 may be electrically connected to the lower semiconductor layer 111L or a first conductivity-type semiconductor layer 112c of a third LED cell 110c in a side portion passing through the lower semiconductor layer 111L.

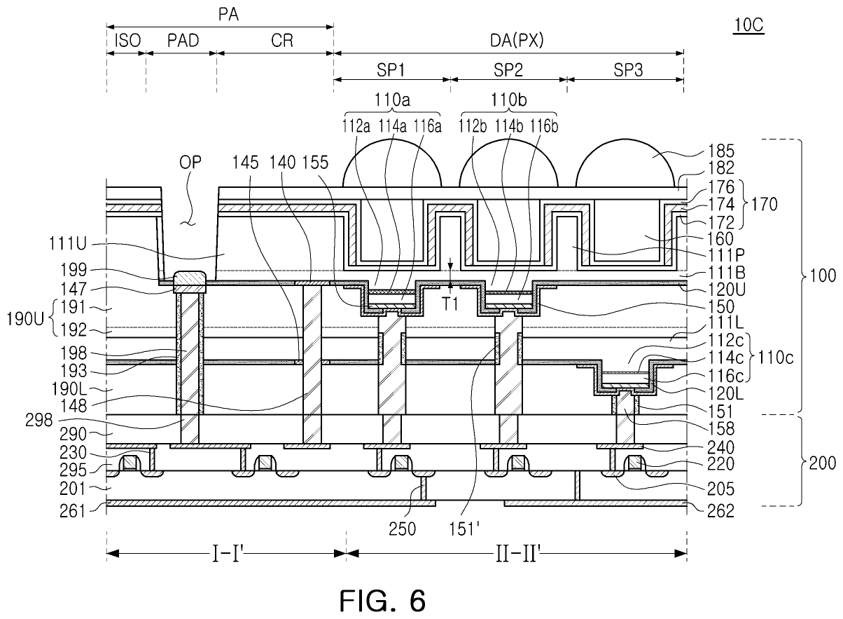

FIG. 6 is a schematic cross-sectional view of a display apparatus 10C according to an example embodiment.

Referring to FIG. 6, a display apparatus 10C of an example embodiment may have the same or similar features as those described with reference to FIGS. 1 to 5, except that a side insulating film 151′ is partially formed. The side insulating film 151′ of the example embodiment may be only partially disposed between a lower semiconductor layer 111L and individual electrodes 158. For example, the side insulating film 151′ may only be formed within a localized range blocking contact between the individual electrodes 158 respectively connected to a first group of LED cells 110a and 110b and the lower semiconductor layer 111L through which the individual electrodes 158 pass.

FIG. 7 illustrates a driving circuit implemented in a display apparatus 10 according to an example embodiment.

Referring to FIG. 7, a circuit diagram of a display apparatus 10 in which n×n sub-pixels are arranged is illustrated. First to third sub-pixels SP1, SP2, and SP3 may respectively receive a data signal through data lines D1 to Dn, which may be vertical paths, for example, in column directions. The first to third sub-pixels SP1, SP2, and SP3 may respectively receive a control signal, e.g., a gate signal, through gate lines G1 to Gn, which may be horizontal paths, for example, in row directions.

A plurality of pixels PX including the first to third sub-pixels SP1, SP2, and SP3 may provide a display region DA, and the display region DA may serve as an active region, and may be a display region for a user. A non-active region NA (or peripheral region PA) may be formed along one or more edges of the display region DA. The non-active region NA may extend along an external periphery of the panel of the display apparatus 10.

First and second driver circuits 12 and 13 may be employed to control operations of the pixels PX, e.g., the first to third sub-pixels SP1, SP2, and SP3. Some or all of the first and second driver circuits 12 and 13 may be implemented on the circuit board 200. The first and second driver circuits 12 and 13 may be formed as integrated circuits, thin film transistor panel circuits, or other suitable circuits, and may be disposed in the non-active region NA of the display apparatus 10. The first and second driver circuits 12 and 13 may include a microprocessor, a memory, such as a storage, a processing circuit, and a communication circuit.

To display an image by the pixels PX, the first driver circuit 12 may supply image data to the data lines D1 to Dn, and may provide a clock signal and other control signals to the second driver circuit 13, which may be a gate driver circuit. The second driver circuit 13 may be implemented using an integrated circuit and/or a thin film transistor circuit. A gate signal for controlling the first to third sub-pixels SP1, SP2, and SP3 arranged in a row direction may be transmitted through the gate lines G1 to Gn of the display apparatus 10.

FIGS. 8A to 8P are cross-sectional views of main processes illustrating a method of manufacturing a display apparatus according to an example embodiment. FIGS. 8A to 8P can be understood as a method for manufacturing the display apparatus 10 of FIG. 3.

Referring to FIG. 8A, a first semiconductor stack body SL1 in which an upper semiconductor layer 111U, a first conductivity-type semiconductor layer 112a, a first active layer 114a, and a second conductivity-type semiconductor layer 116a are sequentially disposed on a growth substrate 101 may be formed.

The growth substrate 101 may be for growing a nitride single crystal, and may include, for example, one or more materials, such as, sapphire, Si, SiC, MgAl₂O₄, MgO, LiAlO₂, LiGaO₂, and/or GaN. In some embodiments, to improve crystallinity and light extraction efficiency of semiconductor layers, the growth substrate 101 may have a convex-convex structure on at least a portion of an upper surface thereof. In this case, a convex-convex structure may also be formed in layers to be grown in an upper portion.

The upper semiconductor layer 111U, the first conductivity-type semiconductor layer 112a, the first active layer 114a, and the second conductivity-type semiconductor layer 116a may be formed, for example, using a metal organic chemical vapor deposition (MOCVD) process, a hydrogen vapor phase epitaxy (HVPE) process, or a molecular beam epitaxy (MBE) process. The first conductivity-type semiconductor layer 112a may be an n-type nitride semiconductor layer, such as n-type GaN, and the second conductivity-type semiconductor layer 116a may be a p-type nitride semiconductor layer, such as p-type GaN/p-type AlGaN. The first active layer 114a may have a multi-quantum well structure, such as InGaN/GaN. In some embodiments, the upper semiconductor layer 111U may include a buffer layer and an undoped nitride layer (e.g., GaN). In this case, the buffer layer may be for alleviating lattice defects of the first conductivity-type semiconductor layer 112a, and may include an undoped nitride semiconductor, such as undoped GaN, undoped AlN, or undoped InGaN.

Referring to FIG. 8B, the first semiconductor stack body SL1 may be etched to form first LED cells 110a. The first semiconductor stack body SL1 may be partially removed by a dry etching process, and may be etched to have an inclined side surface. Additionally, partially damaged regions DR may be formed on the side surfaces of the first LED cells 110a by the dry etching process.

Subsequently, a second semiconductor stack body SL2 may be formed on the upper semiconductor layer 111U. The second semiconductor stack body SL2 may be an epitaxial layer regrown on the upper semiconductor layer 111U, and may include a first conductivity-type semiconductor layer 112b, a second active layer 114b, and a second conductivity-type semiconductor layer 116b.

Referring to FIG. 8C, the second semiconductor stack body SL2 may be etched to form second LED cells 110b. The second semiconductor stack body SL2 may be partially removed by a dry etching process, and may be etched to have an inclined side surface. Additionally, partially damaged regions DR may be formed on the side surfaces of the second LED cells 110b by the dry etching process. The first LED cells 110a and the second LED cells 110b may share a first conductivity-type semiconductor base layer 111B of the upper semiconductor layer 111U.

Referring to FIG. 8D, contact layers 155 may be formed. The contact layers 155 may be formed on the first LED cells 110a and the second LED cells 110b. The contact layers 155 may be formed on upper surfaces of the second conductivity-type semiconductor layers 116a and 116b. For example, the contact layers 155 may be highly reflective ohmic contact layers.

Subsequently, an upper passivation layer 120U may be formed. The upper passivation layer 120U may be formed to remove the damaged regions DR of the first LED cells 110a and the second LED cells 110b and to cover the upper semiconductor layer 111U, the first LED cells 110a, the second LED cells 110b, and the contact layers 155. The upper passivation layer 120U may be formed on the upper semiconductor layer 111U to have a uniform thickness.

The damaged regions DR may be selectively removed by, for example, a wet etching process. During the wet etching process, by controlling process conditions such that selectivity between crystal planes is different to be etched, only the damaged regions DR may be selectively removed. As a result, an angle between an upper surface and side surfaces of the LED cells 110a and 110b may be vertical or close to vertical, and non-radiative recombination due to the damaged regions DR may be reduced, thereby improving luminance.

Thereafter, the upper semiconductor layer 111U and the upper passivation layer 120U may be removed by a predetermined depth from an edge region (“ISO” in FIG. 3) of the upper semiconductor layer 111U. The edge region ISO may be a region that may be cut in a subsequent process, and may be a region for separating modules. Therefore, to reduce or prevent cracks from occurring during a cutting or dicing process, a portion of the upper semiconductor layer 111U may be removed in this operation.

Referring to FIG. 8E, an upper common electrode pad 140, electrode pads 150, and a lower connection pad 147 may be formed. The upper common electrode pad 140 may be formed to pass through the upper passivation layer 120U and to contact the first conductivity-type semiconductor base layer 111B. The upper common electrode pad 140 may be formed in the connection region CR of FIG. 3. The electrode pads 150 may be conformally formed on the upper passivation layer 120U to at least partially surround the side surfaces of the first LED cells 110a and the second LED cells 110b. The electrode pads 150 may have a substantially uniform thickness. Lower connection pads 147 may be formed on the upper passivation layer 120U. The lower connection pads 147 may be formed in the pad region PAD of FIG. 3. The upper common electrode pad 140, the electrode pads 150, and the lower connection pad 147 may be formed together by the same process, but the present inventive concept is not limited thereto. The upper common electrode pad 140, the electrode pads 150, and the lower connection pad 147 may include a conductive material, for example, metal.

Referring to FIG. 8F, a structure including the first and second LED cells 110a and 110b and a third semiconductor stack body SL3 may be bonded. The structure including the first and second LED cells 110a and 110b and the third semiconductor stack body SL3 may be bonded by dielectric-dielectric bonding between a first insulating material layer 191 and a second insulating material layer 192. The third semiconductor stack body SL3 may include a lower semiconductor layer 111L, a first conductivity-type semiconductor layer 112c, a third active layer 114c, and a second conductivity-type semiconductor layer 116c, grown on a separate growth substrate. Additionally, a contact layer 155 and the second insulating material layer 192 may be formed in upper and lower portions of the third semiconductor stack body SL3, respectively. The first insulating material layer 191 and the second insulating material layer 192 may be formed to have a flat bonding surface using, for example, a planarization process, such as a chemical mechanical polishing (CMP) process, or an etch-back process.

Referring to FIG. 8G, the third semiconductor stack body SL3 may be etched to form second LED cells 110c. The third semiconductor stack body SL3 may be partially removed by a dry etching process, and may be etched to have an inclined side surface. Additionally, partially damaged regions DR may be formed on the side surfaces of the third LED cells 110c by the dry etching process. The contact layer 155 may be etched to correspond to an area of the second conductivity-type semiconductor layer 116c.

Referring to FIG. 8H, a lower passivation layer 120L may be formed. The lower passivation layer 120L may be formed to remove the damaged regions DR of the third LED cells 110c and to be on and at least partially cover the lower semiconductor layer 111L, the third LED cells 110c, and the contact layer 155. The lower passivation layer 120L may be formed on the lower semiconductor layer 111L to have a uniform thickness.

Subsequently, a lower common electrode pad 145 and an electrode pad 150 may be formed. The lower common electrode pad 145 may be formed to pass through the lower passivation layer 120L and to contact the lower semiconductor layer 111L. The lower common electrode pad 145 may be formed in a position vertically overlapping the upper common electrode pad 140 as shown in FIG. 8H. Electrode pads 150 may be formed conformally on the lower passivation layer 120L to at least partially surround a side surface of the third LED cell 110c.

Referring to FIG. 8I, a lower insulating layer 190L may be formed on the lower passivation layer 120L. The lower insulating layer 190L may include the same as or different material from the upper insulating layer 190U. The lower insulating layer 190L may be, for example, tetraethyl-ortho-silicate (TEOS), undoped silicate glass (USG), phosphosilicate glass (PSG), borosilicate glass (BSG), borophosphosilicate glass (BPSG), fluoride silicate glass (FSG), spin-on-glass (SOG), Tonen silazene (TOSZ), or a combination thereof.

Referring to FIG. 8J, via holes TH1, TH2, and TH3, passing through the lower insulating layer 190L, the lower semiconductor layer 111L, and/or the upper insulating layer 190U, may be formed. A first via hole TH1 may pass through the lower insulating layer 190L, the lower semiconductor layer 111L, and the upper insulating layer 190U, and may expose at least a portion of the lower connection pad 147. A second via hole TH2 may pass through the lower insulating layer 190L, the lower semiconductor layer 111L, and the upper insulating layer 190U, and may expose at least a portion of the upper common electrode pad 140. The second via hole TH2 may pass through the lower common electrode pad 145. Third via holes TH3 may pass through the lower insulating layer 190L, the lower semiconductor layer 111L, and the upper insulating layer 190U, and may expose the electrode pads 150 on the first LED cell 110a and the second LED cell 110b. Additionally, the third via holes TH3 may pass through only the lower insulating layer 190L and may expose the electrode pad 150 on the third LED cell 110c.

Next, side insulating films 151 and 193 may be formed. The side insulating films 151 and 193 may be selectively formed only on sidewalls of the first via holes TH1 and the third via holes TH3.

Referring to FIG. 8K, electrodes 148, 158, and 198 at least partially filling the via holes may be formed. Common electrodes 148 may be connected to the upper common electrode pad 140 and the lower common electrode pad 145. Individual electrodes 158 may be connected to the electrode pads 150 on the first to third LED cells 110a, 110b, and 110c. Connection electrodes 198 may be connected to the lower connection pad 147.

Referring to FIG. 8L, a structure including the first to third LED cells 110a, 110b, and 110c and a circuit board 200 may be bonded. The circuit board 200 may be prepared by a separate process. The structure and the circuit board 200 may be bonded on a wafer level by a wafer bonding process. The electrodes 148, 158, and 198 of the structure may be bonded to bonding electrodes 298, and the lower insulating layer 190L may be bonded to a bonding insulating layer 290.

Referring to FIG. 8M, the growth substrate 101 may be removed from the upper semiconductor layer 111U, and a portion of the upper semiconductor layer 111U may be removed. The growth substrate 101 may be removed by various processes such as a laser lift-off process, a mechanical polishing process, a mechanical chemical polishing process, or an etching process. For example, the upper semiconductor layer 111U may be partially removed to reduce a predetermined thickness using a polishing process such as CMP. In the following drawings, to facilitate understanding, the structure including the first to third LED cells 110a, 110b, and 110c is illustrated in a vertically symmetrical form, as illustrated in FIG. 8L.

Referring to FIG. 8N, a partition structure 111P defining sub-pixel spaces OP1, OP2, and OP3 may be formed in the upper semiconductor layer 111U. The partition structure 111P may be formed using an etching process to form openings in regions corresponding to the LED cells in the upper semiconductor layer 111U. Each of the openings may be provided as first to third sub-pixel spaces OP1, OP2, and OP3, corresponding to the first to third sub-pixels SP1, SP2, and SP3 in FIG. 3. The corresponding first to third sub-pixel spaces OP1, OP2, and OP3 may be formed by a depth in which the upper semiconductor layer 111U may not be completely separated between the first and second LED cells 110a and 110b.

Referring to FIG. 8O, a partition reflective layer 170 may be formed on the partition structure 111P. The partition reflective layer 170 may be prepared by forming a first partition insulating film 172 and a reflective metal film 174, removing a portion of the reflective metal film 174 from bottom surfaces of the first to third sub-pixel spaces OP1, OP2, and OP3, and forming a second partition insulating film 176.

For example, the first and second partition insulating films 172 and 176 may be formed using atomic layer deposition (ALD). Therefore, the first and second partition insulating films 172 and 176 may have substantially the same thickness on the upper surface and side walls of the partition structure 111P, respectively. The reflective metal film 174 may be formed using a sputtering or CVD process.

Referring to FIG. 8P, transparent resin portions 160 and a planarization layer 182 may be formed in the first to third sub-pixel spaces OP1, OP2, and OP3, and microlenses 185 may be formed on the planarization layer 182. The transparent resin portions 160 may include a transparent resin, such as a silicone resin or an epoxy resin.

Next, an opening OP may be formed on the lower connection pad 147, and a portion of the upper passivation layer 120U exposed through the opening OP may be removed, and then the upper connection pad 199 of FIG. 3 may be formed. Thereafter, the display apparatus 10 may be finally manufactured by dicing adjacent modules in an edge region ISO (see FIG. 3).

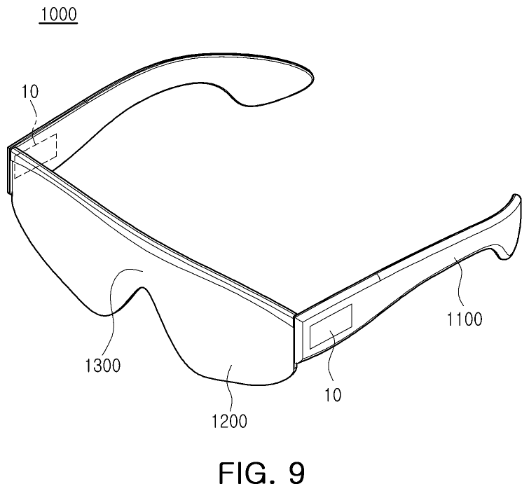

FIG. 9 is a conceptual diagram of an electronic device 1000 to which a display apparatus 10 of an example embodiment is applied.

Referring to FIG. 9, an electronic device 1000 according to the present embodiment may be a glasses-type display, which may be a wearable device. The electronic device 1000 may include a pair of temples 1100, a pair of optical coupling lenses 1200, and a bridge 1300. The electronic device 1000 may further include a display apparatus 10 including an image generator.

The electronic device 1000 may be a head-mounted, glasses-type, or goggle-type virtual reality (VR) device that may provide virtual reality or provide both virtual images and actual external scenery, an augmented reality (AR) device, or a mixed reality (MR) device.

The temples 1100 may extend in one direction. The temples 1100 may be spaced apart from each other, and may extend in parallel. The temples 1100 may be folded toward the bridge 1300. The bridge 1300 may be provided between the optical coupling lenses 1200 to connect the optical coupling lenses 1200 to each other. The optical coupling lenses 1200 may include a light guide plate. The display apparatus 10 may be disposed on each of the temples 1100, and may generate an image on the optical coupling lenses 1200. The display apparatus 10 may be a display apparatus according to the embodiments described above with reference to FIGS. 1 to 7.

According to embodiments, a display apparatus having improved manufacturing process efficiency may be provided by combining LED cells grown on the same substrate and LED cells grown on a separate substrate.

Various advantages and effects of the present inventive concept are not limited to the above-described content, and can be more easily understood through description of specific embodiments.

While example embodiments have been illustrated and described above, it will be apparent to those skilled in the art that modifications and variations could be made without departing from the scope of the present inventive concept as defined by the appended claims.

What is claimed is:

1. A display apparatus comprising:
a circuit board comprising a driving circuit; and
a pixel array on the circuit board, in which pixel units respectively including a plurality of sub-pixels are arranged, the pixel array including a plurality of LED cells corresponding to the plurality of sub-pixels, respectively,
wherein the pixel array further includes:
a first semiconductor layer having a first LED cell and a second LED cell, facing the circuit board;
a first passivation layer on at least a portion of the first LED cell and on at least a portion of the second LED cell;
first and second electrode pads passing through the first passivation layer and respectively electrically connected to the first and second LED cells;
a first common electrode pad passing through the first passivation layer and electrically connected to the first semiconductor layer;
a first insulating layer between the first passivation layer and the circuit board;
a second semiconductor layer between the first insulating layer and the circuit board and having a third LED cell facing the circuit board;
a second passivation layer on at least a portion of the third LED cell;
a third electrode pad passing through the second passivation layer and electrically connected to the third LED cell;
a second insulating layer between the second passivation layer and the circuit board;
individual electrodes passing through one or more of the first insulating layer, the second insulating layer, and the second semiconductor layer, and electrically connecting the first to third electrode pads and the driving circuit; and
a common electrode passing through the first and second insulating layers and the second semiconductor layer, and electrically connecting the first common electrode pad and the driving circuit.

2. The display apparatus of claim 1, wherein the first LED cell comprises a first active layer, the second LED cell comprises a second active layer, and the third LED cell comprises a third active layer,
wherein the first active layer, the second active layer, and the third active layer are configured to emit light of different wavelengths.

3. The display apparatus of claim 2, wherein the first and second active layers are configured to emit light having a wavelength of about 440 nm to about 480 nm or light having a wavelength of about 510 nm to about 550 nm,
wherein the third active layer is configured to emit light having a wavelength of about 610 nm to about 650 nm.

4. The display apparatus of claim 1, wherein a gap between the third LED cell and the circuit board is smaller than a gap between the first LED cell and the circuit board and between the second LED cell and the circuit board.

5. The display apparatus of claim 1, wherein the third LED cell does not overlap the first and second LED cells in a direction perpendicular to a plane defined by the circuit board and in a direction parallel to a plane defined by the circuit board.

6. The display apparatus of claim 1, wherein the first semiconductor layer comprises a first conductivity-type semiconductor layer constituting the first and second LED cells, and
wherein the second semiconductor layer comprises a first conductivity-type semiconductor layer constituting the third LED cell.

7. The display apparatus of claim 6, wherein the first conductivity-type semiconductor layer of the first semiconductor layer is a nitride semiconductor layer, and
wherein the first conductivity-type semiconductor layer of the second semiconductor layer is a phosphide semiconductor layer or an arsenide semiconductor layer.

8. The display apparatus of claim 1, further comprising a side insulating film surrounding at least a portion of the individual electrodes.

9. The display apparatus of claim 8, wherein the side insulating film is between the second semiconductor layer and the individual electrodes.

10. The display apparatus of claim 1, wherein at least a portion of a side surface of the common electrode is in contact with the second semiconductor layer.

11. The display apparatus of claim 10, further comprising a second common electrode pad electrically connected to a lower surface of the second semiconductor layer, wherein the common electrode passes through the second common electrode pad.

12. The display apparatus of claim 1, wherein the first semiconductor layer comprises:
a first conductivity-type semiconductor base layer shared by the first and second LED cells; and
first conductivity-type semiconductor layers, active layers, and second conductivity-type semiconductor layers, sequentially arranged between the first conductivity-type semiconductor base layer and the circuit board to configure the first and second LED cells.

13. The display apparatus of claim 1, wherein the second semiconductor layer comprises a first conductivity-type semiconductor layer, an active layer, and a second conductivity-type semiconductor layer, sequentially arranged to configure the third LED cell.

14. The display apparatus of claim 1, wherein the first semiconductor layer includes a partition structure defining a plurality of sub-pixel spaces respectively corresponding to the first LED cell, the second LED cell, and the third LED cell,
wherein the display apparatus further comprises:
transparent resin portions within the plurality of sub-pixel spaces; and
microlenses on the transparent resin portions.

15. A display apparatus comprising:
a circuit board including a driving circuit and bonding electrodes electrically connected to the driving circuit; and
a pixel array on the circuit board and in which pixel units respectively including a plurality of sub-pixels are arranged,
wherein the pixel array includes:
a plurality of LED cells corresponding to the plurality of sub-pixels, respectively, each of the plurality of LED cells including a first conductivity-type semiconductor layer, an active layer, and a second conductivity-type semiconductor layer, the plurality of LED cells including a first group of LED cells, and a second group of LED cells, located on different levels in a direction perpendicular to a plane defined by the circuit board;
electrode pads electrically connected to the second conductivity-type semiconductor layer of each of the plurality of LED cells;
a first common electrode pad electrically connected to the first conductivity-type semiconductor layer of the first group of LED cells;
a second common electrode pad electrically connected to the first conductivity-type semiconductor layer of the second group of LED cells;
a common electrode electrically connecting the first and second common electrode pads and one of the bonding electrodes corresponding thereto; and
individual electrodes electrically connecting the electrode pads to the corresponding bonding electrodes,
wherein a number of the first group of LED cells is different from a number of the second group of LED cells.

16. The display apparatus of claim 15, wherein the first group of LED cells are configured to emit green light, blue light, or both the green light and the blue light, and
wherein the second group of LED cells are configured to emit red light.

17. The display apparatus of claim 16, wherein the number of the second group of LED cells is less than the number of the first group of LED cells.

18. A display apparatus comprising:
a circuit board comprising a driving circuit; and
a pixel array on the circuit board, and in which pixel units respectively including a plurality of sub-pixels are arranged,
wherein the pixel array includes:
a plurality of LED cells corresponding to the plurality of sub-pixels, respectively, and respectively including a first conductivity-type semiconductor layer, an active layer, and a second conductivity-type semiconductor layer;
a common electrode electrically connecting the first conductivity-type semiconductor layer of each of the plurality of LED cells and the driving circuit; and
individual electrodes electrically connecting the second conductivity-type semiconductor layer of each of the plurality of LED cells and the driving circuit,
wherein the plurality of LED cells includes a first LED cell, a second LED cell, and a third LED cell, configured to emit light of different wavelengths,
wherein the first LED cell and the second LED cell are located on a first level from the circuit board, and
wherein the third LED cell is located on a second level, lower than the first level from the circuit board, such that the second level is closer to the circuit board than the first level.

19. The display apparatus of claim 18, wherein the first LED cell and the second LED cell are configured to emit green light, blue light, or both the green light and the blue light, and
wherein the third LED cell is configured to emit red light.

20. The display apparatus of claim 18, wherein the first LED cell, the second LED cell, and the third LED cell do not overlap each other in a direction perpendicular to a plane defined by the circuit board.
